(19) United States
(12) Patent Application Publication
(10) Pub. No.: US 2025/0079194 A1
(43) Pub. Date: Mar. 6, 2025

(54) METHODS AND APPARATUS FOR A GAS LINE MATRIX AND INTERCHANGE ASSEMBLY

(71) Applicant: ASM IP Holding B.V., Almere (NL)

(72) Inventor: Hannelore Azora Hemminger, Tempe, AZ (US)

(21) Appl. No.: 18/817,489

(22) Filed: Aug. 28, 2024

Related U.S. Application Data
(60) Provisional application No. 63/536,047, filed on Aug. 31, 2023.

(51) Int. Cl. H01L 21/67

(52) U.S. Cl. CPC H01L 21/67017

(57) ABSTRACT

Various embodiments of the present technology may provide a gas line matrix and interchange assembly. The wherein the interchange assembly includes a first plurality of gas lines, wherein each gas line comprises a first end and a second end, and wherein the first ends of the first plurality of gas lines align on a first axis and the second ends of the first plurality of gas lines aligns on a second axis, and the first axis is perpendicular to the second axis.

### CROSS-REFERENCE TO RELATED APPLICATIONS

This application is a nonprovisional of, and claims priority to and the benefit of, U.S. Provisional Patent Application No. 63/536,047, filed Aug. 31, 2023 and entitled “METHODS AND APPARATUS FOR A GAS LINE MATRIX AND INTERCHANGE ASSEMBLY,” which is hereby incorporated by reference herein.

### FIELD OF INVENTION

The present disclosure generally relates to a method and apparatus for a gas line matrix and interchange assembly. More particularly, the present disclosure relates to a gas line arrangement having a set of sections that align on a single axis.

### BACKGROUND OF THE TECHNOLOGY

Semiconductor equipment needs to route various source vessels and process gasses to a reaction chamber through a valve manifold with multiple ports. For different processes, a given source vessel will need to be routed to different valve manifold port, necessitating different gas lines. Since these gas lines are heated, this can lead to large numbers of unique gas lines and heater jackets, resulting in a complex and chaotic gas line system.

### SUMMARY OF THE INVENTION

Various embodiments of the present technology may provide a gas line matrix and interchange assembly. The wherein the interchange assembly includes a first plurality of gas lines, wherein each gas line comprises a first end and a second end, and wherein the first ends of the first plurality of gas lines align on a first axis and the second ends of the first plurality of gas lines aligns on a second axis, and the first axis is perpendicular to the second axis.

According to one aspect, an apparatus comprises: a gas line matrix; and an interchange assembly coupled to the gas line matrix, wherein the interchange assembly comprises a first plurality of gas lines, wherein each gas line comprises a first end and a second end; wherein: the first ends of the first plurality of gas lines aligns on a first axis and the second ends of the first plurality of gas lines aligns on a second axis, and the first axis is perpendicular to the second axis.

In one embodiment, the gas line matrix comprises a second plurality of gas lines and each gas line from the second plurality of gas lines is coupled to one gas line from the first plurality of gas lines.

In one embodiment, each gas line from the first plurality of gas lines comprises at least one right angle.

In one embodiment, each gas line from the first plurality of gas lines comprises a first section coupled to a second section with a connector, and the first section comprising the first end and the second section comprising the second end.

In one embodiment, the first section is in parallel with the second axis and is perpendicular to the first axis.

In one embodiment, the second section is in parallel with the first axis and perpendicular to the second axis.

In one embodiment, the first section is Z-shaped and the second section is L-shaped.

In one embodiment, the first section is coupled to the second section with a connector.

In one embodiment, each second section has a length that is different from the other second sections.

According to another aspect, a method for assembling a gas line interchange, comprises: selecting a first gas line section from a plurality of first sections based on a first distance, wherein each first section has a first end and a second end; selecting a second gas line section from a plurality of second sections based on a second distance, wherein each second section has a length that is different from the other second sections, and wherein each second section has a first end and a second end connecting the second end of the first section to the first end of the second section; selecting a third gas line section from the plurality of first sections based on third distance; selecting a fourth gas line section from the plurality of second sections based on a fourth distance; and connecting the second end of the third section to the first end of the fourth section; wherein the first ends of the first and third sections align on a first axis; and wherein the second ends of the second and fourth sections align on a second axis that is perpendicular to the first axis.

In one embodiment, the method further comprises connecting the first end of the first gas line section to a gas line matrix and connecting the second end of the second gas line section to a vessel port.

In one embodiment, the first distance is the horizontal distance between the first axis and a vessel port.

In one embodiment, the second distance is the vertical distance between the second axis and the second end of the selected first gas line section.

According to yet another aspect, a system comprises: a reaction chamber; a gas line matrix coupled to the reaction chamber; an interchange assembly coupled to the gas line matrix, wherein the interchange assembly comprises a first plurality of gas lines, wherein each gas line comprises a first end and a second end; wherein the first ends of the first plurality of gas lines aligns on a first axis and the second ends of the first plurality of gas lines aligns on a second axis, and wherein the first axis is perpendicular to the second axis; a gas line matrix coupled between the reaction chamber and the interchange assembly, wherein the gas line matrix comprises a second plurality of gas lines and each gas line from the second plurality of gas lines is coupled to one gas line from the first plurality of gas lines; and a plurality of vessels coupled to the interchange assembly.

In one embodiment, each gas line from the first plurality of gas lines comprises at least one right angle.

In one embodiment, each gas line from the first plurality of gas lines comprises a first section coupled to a second section with a connector, and the first section comprising the first end and the second section comprising the second end.

In one embodiment, the first section is in parallel with the second axis and is perpendicular to the first axis, and wherein the second section is in parallel with the first axis and perpendicular to the second axis.

In one embodiment, each second section has a length that is different from the other second sections.

In one embodiment, the first section is Z-shaped and the second section is L-shaped.

In one embodiment, the first section is coupled to the second section with a first connector, the first section is coupled to the gas matrix with a second connector, and the second section is coupled to a vessel from the plurality of vessels with a third connector.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a first view of a system in accordance with various embodiments of the present technology;

FIG. 2 representatively illustrates a second view of the system in accordance with various embodiments of the present technology;

FIG. 3 representatively illustrates a top view of a first section used in the system in accordance with various embodiments of the present technology;

FIG. 4 representatively illustrates a top view of a set of second sections used in the system in accordance with various embodiments of the present technology; and

FIGS. 5 and 6 are perspective views of a gas line in an interchange assembly in accordance with various embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various reaction chambers, valves and valve manifolds, gas line connectors, and vessels.

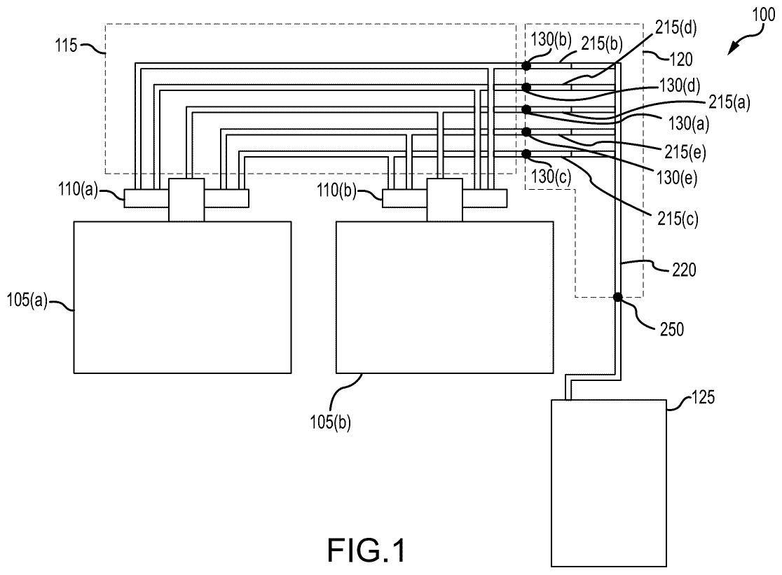

Referring to FIG. 1, an exemplary system 100 may comprise a reaction chamber 105, a valve manifold 110, a source vessel 125, a gas line matrix 115, and an interchange assembly 120. In an exemplary embodiment, the system 100 comprises a first reaction chamber 105 (a) and a second reaction chamber 105 (b). In addition, each reaction chamber 105 is coupled to a respective valve manifold 110. For example, the first reaction chamber 105 (a) is coupled to a first valve manifold 110 (a) and the second reaction chamber 105 (b) is coupled to a second valve manifold 110 (b). Each valve manifold 110 may comprise a plurality of ports for connecting to the gas line matrix 115.

In various embodiments, the source vessel 125 may be configured to contain or secure a solid or liquid chemistry for use during semiconductor processing. In various embodiments, the source vessel may be formed from a metal material, such as stainless steel, a metal alloy, or the like. In an exemplary embodiment, the system 100 may comprise a plurality of source vessels, such as a first source vessel 125 (a), a second source vessel 125 (b), a third source vessel 125 (c), a fourth source vessel 125 (d), and a fifth source vessel 125 (e). In various embodiments, the system 100 may comprise any desired number of source vessels.

In addition, each source vessel 125 may comprise or be coupled to a respective vessel port 250. For example, the first source vessel 125 (a) may connect to or comprise a first vessel port 250 (a), the second source vessel 125 (b) may connect to or comprise a second vessel port 250 (b), the third source vessel 125 (c) may connect to or comprise a third vessel port 250 (c), the fourth source vessel 125 (d) may connect to or comprise a fourth vessel port 250 (d), and the fifth source vessel 125 (e) may connect to or comprise a fifth vessel port 250 (e). In an exemplary embodiment, the vessel ports 250 are aligned on a second axis 205. The vessel port 250 may comprise a fitting, gasket or any other suitable coupling.

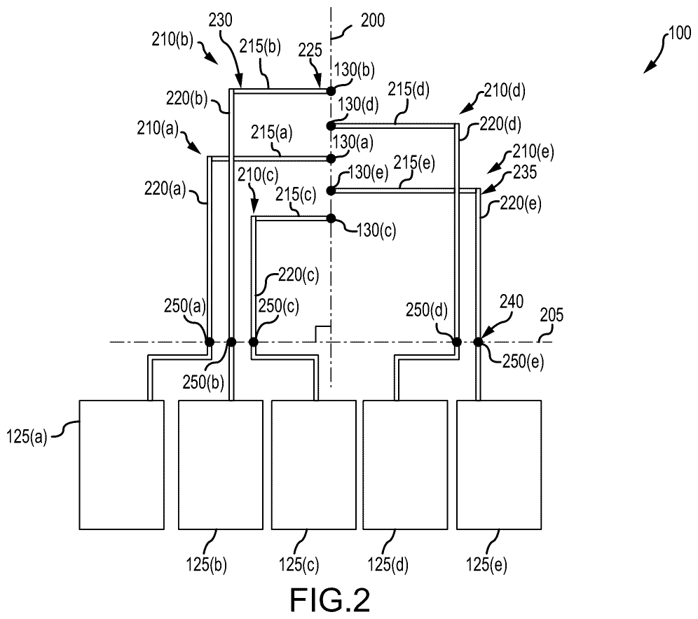

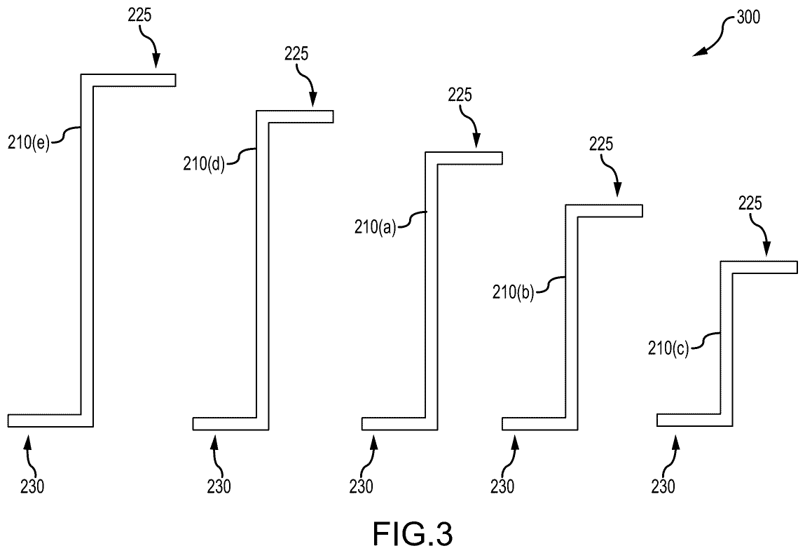

In various embodiments, and referring to FIGS. 2 and 3, the interchange assembly 120 may comprise a first plurality of gas lines 210. The first plurality of gas lines 210 may be coupled to the gas matrix 115 via a plurality of connection joints 130, for example a first connection joint 130 (a), a second connection joint 130 (b), a third connection joint 130 (c), a fourth connection joint 130 (d), and a fifth connection joint 130 (e). In some embodiments, the connection joint 130 may comprise a gasket, fitting, or any other suitable coupling. In an exemplary embodiment, the plurality of connection joints 130 align on a first axis 200. In addition, each connection joint 130 connects to only one gas line 210 from the first plurality of gas lines.

Each gas line from the first plurality of gas lines may comprise a first section 215 and a second section 220. For example, a first gas line 210 (a) may comprise a first section 215 (a) and a second section 220 (a), a second gas line 210 (b) may comprise a first section 215 (b) and a second section 220 (b), a third gas line 210 (c) may comprise a first section 215 (c) and a second section 220 (c), a fourth gas line 210 (d) may comprise a first section 215 (d) and a second section 220 (d), and a fifth gas line 210 (e) may comprise a first section 215 (e) and a second section 220 (e).

In various embodiments, the first section 215 may comprise a first end 225 and a second end 230. The first end 225 may be coupled to the gas matrix 115. The second end 230 may be coupled to the second section 220. The first section 215 may be coupled to the second section 220 by a connector. The connector may be any suitable pipe connector or fitting.

In various embodiments, the second section 220 may comprise a first end 235 and a second end 240. The first end 235 of the second section 220 may be coupled to the second end 230 of the first section 215. The second end 240 may be coupled to a single source vessel 125 from the plurality of source vessels 125 via the vessel port 250. For example, the second end 240 may comprise a gasket or fitting that connects to the vessel port 250. Accordingly, the second ends 240 of the second sections 220 will be aligned on the second axis 205.

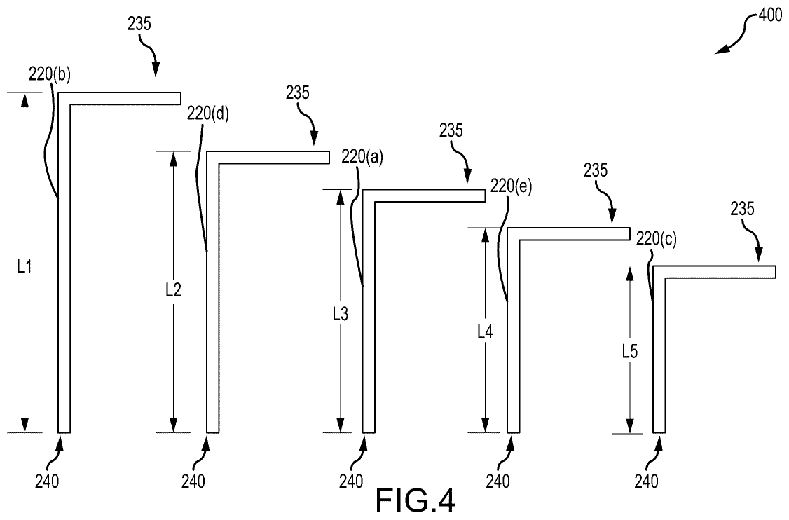

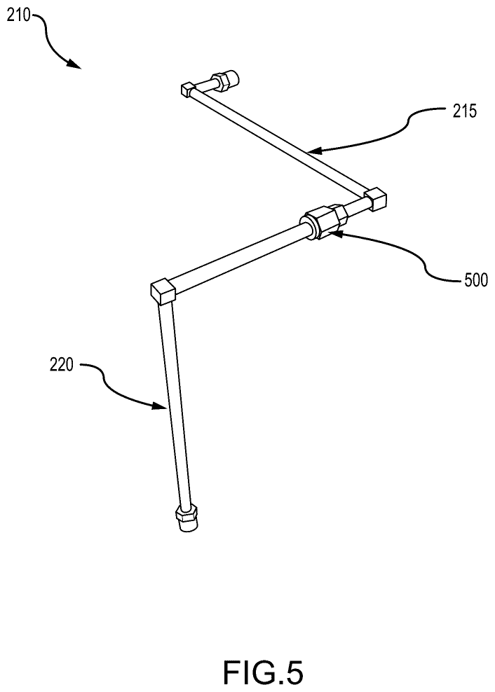

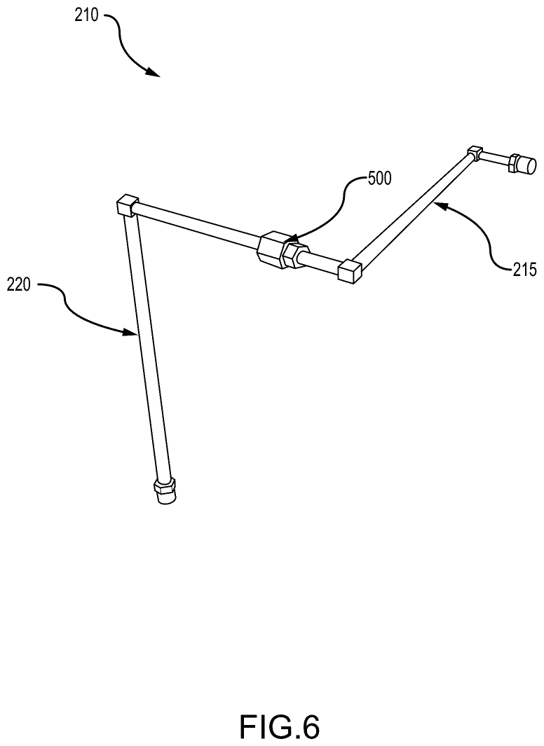

In an exemplary embodiment, the second section 200 may comprise at least one bend. For example, the second section 220 may comprise a right angle. In an exemplary embodiment, the second section is L-shaped, for example, as illustrated in FIGS. 4-6.

Accordingly, each gas line from the first plurality of gas lines may be defined by the sections spanning between the first end 215 of the first section and the second end 240 of the second section.

In various embodiments, the first section 215 may comprise at least two bends. For example, the first section 215 may comprise two right angles. In an exemplary embodiment, the first section 215 is Z-shaped, for example, as illustrated in FIGS. 3, 5 and 6. In addition, at least a portion of the first section 215 may be arranged perpendicular to the second section 220.

In addition, the first sections 215 may be arranged perpendicular to the first axis 200 and parallel to the second axis 205. The second sections 220 may be arranged parallel to the first axis 200 and perpendicular to the second axis 205.

In various embodiments, the first ends 225 of the first sections 215 connect to the connection joints 130. For example, the section 215 (a) may connect to the first connection joint 130 (a), the section 215 (b) may connect to the second connection joint 130 (b), the section 215 (c) may connect to the third connection joint 130 (c), the section 215 (d) may connect to the fourth connection joint 130 (d), the section 215 (e) may connect to the fifth connection joint 130 (e).

In various embodiments, the second ends 240 of the second sections 220 connect to the source vessels. For example, the section 220 (a) may connect to the first source vessel 125 (a), the section 220 (b) may connect to the second source vessel 125 (b), the section 220 (c) may connect to the third source vessel 125 (c), the section 220 (d) may connect to the fourth source vessel 220 (d), and the section 220 (e) may connect to the fifth source vessel 220 (e). The interchange assembly 120 may connect to the source vessels 125 via any number or type of pipe connectors or fittings.

In an exemplary embodiment, and referring to FIG. 4, each second section 220 has a length that is different from the other second sections. For example, the section 220 (a) has a first length L1, section 220 (b) has a second length L2, section 220 (c) has a third length L3, section 220 (d) has a fourth length L4, and section 220 (e) has a fifth length L5, wherein L1≠L2≠L3≠L4≠L5.

In various embodiments, the gas line matrix 115 may comprise a second plurality of gas lines that connect to desired connection joint 130 based on the type of chemistry needed for a particular reaction chamber 105. Accordingly, each gas line from the second plurality of gas lines is coupled to a single gas line 210 from the first plurality of gas lines.

In various embodiments, a method for assembling a gas line interchange may comprise selecting a first gas line section (e.g., 210 (a)) from a plurality of first sections 300 based on a first distance. The first distance may be the horizontal distance between the first axis 200 and the vessel port 250 for the desired source vessel 125. For example, a shorter distances will necessitate a shorter first gas line section 210, and longer distances will necessitate a longer first gas line section 210.

The method may further comprise connecting the first end 225 of the first section to the desired connection joint 130. The particular connection joint 130 is selected based on the desired routing of the chemistry in the source vessel 125 to the appropriate/desired reaction chamber 105 and/or port on the valve manifold 110.

The method may further comprises selecting a second gas line section (for example 220(a)) from a plurality of second sections 400 based on a second distance. The second distance may be the vertical distance between the second axis 205 and the second end 230 of the selected first gas line section 210. For example, shorter distances will necessitate a shorter second gas line section 220 and longer distances will necessitate a longer second gas line section 200.

The method may further comprise connecting the second end 230 of the first section 210 to the first end 235 of the second section 220 and connecting the second end 240 of the second section 220 to the desired vessel port 250.

The method may comprise repeating selecting and connecting the first and second sections 215, 220 as described above to form any desired number of gas lines 210.

As described above the first ends of the first sections align on the first axis 200, and the second ends of the second sections align on the second axis 205, which is perpendicular to the first axis 200.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system. The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a gas line matrix; and
an interchange assembly coupled to the gas line matrix, wherein the interchange assembly comprises a first plurality of gas lines, wherein each gas line comprises a first end and a second end;
wherein:
the first ends of the first plurality of gas lines aligns on a first axis and the second ends of the first plurality of gas lines aligns on a second axis, and
the first axis is perpendicular to the second axis.

2. The apparatus according to claim 1, wherein the gas line matrix comprises a second plurality of gas lines and each gas line from the second plurality of gas lines is coupled to one gas line from the first plurality of gas lines.

3. The apparatus according to claim 1, wherein each gas line from the first plurality of gas lines comprises at least one right angle.

4. The apparatus according to claim 1, wherein each gas line from the first plurality of gas lines comprises a first section coupled to a second section with a connector, and the first section comprising the first end and the second section comprising the second end.

5. The apparatus according to claim 4, wherein the first section is in parallel with the second axis and is perpendicular to the first axis.

6. The apparatus according to claim 5, wherein the second section is in parallel with the first axis and in perpendicular to the second axis.

7. The apparatus according to claim 4, wherein the first section is Z-shaped and the second section is L-shaped.

8. The apparatus according to claim 4, wherein the first section is coupled to the second section with a connector.

9. The apparatus according to claim 4, wherein second section has a length that is different from the other second sections.

10. A method for assembling a gas line interchange, comprising:
selecting a first gas line section from a plurality of first sections based on a first distance, and each first section has a first end and a second end;
selecting a second gas line section from a plurality of second sections based on a second distance, wherein each second section has a length that is different from the other second sections, and wherein each second section has a first end and a second end;
connecting the second end of the first section to the first end of the second section;
selecting a third gas line section from the plurality of first sections based on third distance;
selecting a fourth gas line section from the plurality of second sections based on a fourth distance; and
connecting the second end of the third section to the first end of the fourth section;
wherein the first ends of the first and third sections align on a first axis; and
wherein the second ends of the second and fourth sections align on a second axis that is perpendicular to the first axis.

11. The method according to claim 10, further comprising connecting the first end of the first gas line section to a gas line matrix and connecting the second end of the second gas line section to a vessel port.

12. The method according to claim 11, wherein the first distance is the horizontal distance between the first axis and a vessel port.

13. The method according to claim 12, wherein the second distance is the vertical distance between the second axis and the second end of the selected first gas line section.

14. A system, comprising:
a reaction chamber;
a gas line matrix coupled to the reaction chamber;
an interchange assembly coupled to the gas line matrix, wherein the interchange assembly comprises a first plurality of gas lines, wherein each gas line comprises a first end and a second end;
wherein the first ends of the first plurality of gas lines aligns on a first axis and the second ends of the first plurality of gas lines aligns on a second axis, and wherein the first axis is perpendicular to the second axis;
a gas line matrix coupled between the reaction chamber and the interchange assembly, wherein the gas line matrix comprises a second plurality of gas lines and each gas line from the second plurality of gas lines is coupled to one gas line from the first plurality of gas lines; and
a plurality of vessels coupled to the interchange assembly.

15. The system according to claim 14, wherein each gas line from the first plurality of gas lines comprises a first section coupled to a second section with a connector, and the first section comprising the first end and the second section comprising the second end.

16. The system according to claim 15, wherein the first section is in parallel with the second axis and is perpendicular to the first axis, and wherein the second section is in parallel with the first axis and perpendicular to the second axis.

17. The system according to claim 15, wherein each second section has a length that is different from the other second sections.

18. The system according to claim 14, wherein the first section is Z-shaped.

19. The system according to claim 14, wherein the second section is L-shaped.

20. The system according to claim 14, wherein the first section is coupled to the second section with a first connector, the first section is coupled to the gas matrix with a second connector, and the second section is coupled to a vessel from the plurality of vessels with a third connector.
